(19) United States
(12) Patent Application Publication
(10) Pub. No.: US 2019/0059158 A1
(43) Pub. Date: Feb. 21, 2019

(54) USE OF RF DRIVEN COHERENCE BETWEEN CONDUCTIVE PARTICLES FOR RFID ANTENNAS

(71) Applicant: AVERY DENNISON RETAIL INFORMATION SERVICES, LLC, Mentor, OH (US)

(72) Inventor: Ian J. FORSTER, Chelmsford (GB)

(21) Appl. No.: 16/105,575

(22) Filed: Aug. 20, 2018

Related U.S. Application Data
(60) Provisional application No. 62/546,825, filed on Aug. 17, 2017.

(51) Int. Cl. H05K 3/12; H05K 1/09; H05K 1/16; B41M 3/00; B41M 7/00; H01Q 1/38

(52) U.S. Cl. CPC H05K 3/1283; H05K 1/092; H05K 1/16; H05K 2201/10098; B41M 7/0081; H01Q 1/38; B41M 3/006

(57) ABSTRACT

A method of increasing conductivity in ink using radio frequency energy. A conductive ink comprising a plurality of conductive particles and a binder is printable on a surface, such as a RF antenna. A RF source is used to apply a RF signal to the conductive ink to decrease electrical resistance in the conductive particles via coherence. Once the conductive particles are sufficiently cohered in a state of lower resistance, the binder is cured to maintain the state of lower electrical resistance and improved conductivity of the conductive ink.

### CROSS-REFERENCE TO RELATED APPLICATION(S)

The present application claims priority to and the benefit of U.S. provisional application No. 62/546,825 filed on Aug. 17, 2018, which is incorporated by reference herein in its entirety.

### BACKGROUND

Powdered metals were initially used in early radio detection. An early radio detector, known as a coherer, is generally accepted to have first been discovered in the 1850's. Its first known use as a detector of radio waves occurred in the 1880's. Guglielmo Marconi is credited with being the first to use radio wave detection and signaling for practical purposes. Marconi used coherers in his early experiments and notable events, such as the first transatlantic radio transmission.

During that time period, the coherer was made by placing fine metal particles in a glass tube with contacts at either end of the tube. Due to oxidation and generally poor particle to particle contact, these materials had a relatively high initial resistance. However, application of a radio frequency (RF) signal significantly decreased the resistance to a relatively low resistance. Professor Edouard Branley, a pioneer of using this type of device as a detector, measured a decrease in resistance of from approximately 8000 ohms to seven ohms in one design following coherence.

Once this type of device was in a cohered state, it was permanently cohered unless a mechanical force sufficient to break the particles apart was applied. This force was achieved in early radio detectors by using a tapper. The tapper was typically a small hammer attached to a bell circuit triggered by the low resistance, allowing the reception of Morse code.

The electronics industry currently uses conductive inks, generally made by suspending conductive particles inside some form of printable, primarily nonconductive matrix, for a wide variety of applications. One difficulty with these materials is that the conductivity is related both the quantity and shape of these particles and how closely the particles are positioned to one another. While sintering, using heat and pressure, may force the conductive particles closer together, it is not practical in high speed production. Another problem is that the formation of oxide layers on the surface of the conductive particles prevents good particle to particle connection. This may be partially addressed by adding a reducing agent to the ink to convert the oxide back to the basic metal, or an organo-metallic that converts to metal filler when decomposed.

Conductive particle materials, such as copper and silver, are relatively expensive. Methods of minimizing the amount of material necessary and improving conductivity of the material are required. Thus, there exists a need for an improved conductive printable ink. The present invention discloses a method of decreasing the electrical resistance of conductive particles for a new and novel purpose related to improving the conductivity of printable inks.

### SUMMARY

The following presents a simplified summary in order to provide a basic understanding of some aspects of the disclosed innovation. This summary is not an extensive overview, and it is not intended to identify key/critical elements or to delineate the scope thereof. Its sole purpose is to present some concepts in a simplified form as a prelude to the more detailed description that is presented later.

The subject matter disclosed and claimed herein, in one aspect thereof, comprises a method of increasing conductivity in ink. The method comprises selecting an ink comprised of a plurality of conductive particles and a binder. The ink is then printed onto a surface. Once the ink is printed, a radio frequency (RF) source is applied to the ink to decrease the electrical resistance of the ink. Once the resistance is lowered, the binder is cured to maintain the lowered resistance in the ink.

In accordance with another embodiment, a method of preparing a conductive surface is disclosed. The method comprises printing an ink comprising a plurality of conductive particles and a binder. The ink is printed onto a surface, such as an antenna. Once the ink is printed, a radio frequency source is applied to the ink to lower the electrical resistance in the ink by cohering the plurality of conductive particles. Then, it is determined if a desired level of coherence has occurred. If so, the binder is cured. If not, the radio frequency source is reapplied until the desired level of coherence is detected, and the binder is cured.

In accordance with another embodiment, a conductive ink printable on a surface is disclosed. The conductive ink comprises a plurality of conductive particles and a binder. In response to a RF signal, at least one of the plurality of conductive particles is repositioned with respect to another of the plurality of conductive particles to lower resistance and improve conductivity in the conductive ink. Once repositioned, the binder is cured thereby maintaining the repositioning of the conductive particles.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and is intended to include all such aspects and their equivalents. Other advantages and novel features will become apparent from the following detailed description when considered in conjunction with the drawings.

### BRIEF DESCRIPTION OF THE DRAWINGS

FIG. 1A illustrates a top view of a conductive structure comprising a plurality of conductive particles arranged in a first orientation in accordance with the disclosed architecture.

FIG. 1B illustrates a top view of the conductive structure where the plurality of conductive particles are arranged in a second orientation in accordance with the disclosed architecture.

FIG. 2A illustrates a side view of the conductive structure coupled to a RF source in accordance with the disclosed architecture.

FIG. 2B illustrates a top view of the conductive structure coupled to the RF source in accordance with the disclosed architecture.

FIG. 3 illustrates a top view of the conductive structure printed onto an antenna employing a direct contact RF source in accordance with the disclosed architecture.

FIG. 4 illustrates a top view of the conductive structure printed on the antenna comprising a plurality of contacts in accordance with the disclosed architecture.

FIG. 5 illustrates a top view of the conductive structure printed on the antenna employing a non-contact RF source in accordance with the disclosed architecture.

FIG. 6 illustrates a flow chart of steps for a method of increasing conductivity in ink in accordance with the disclosed architecture.

FIG. 7 illustrates a flow chart of steps for a method of preparing a conductive structure on a surface in accordance with the disclosed architecture.

FIG. 8 illustrates a top view of the conductive structure printed onto an adhesive in accordance with the disclosed architecture.

FIG. 9 illustrates a top view of the conductive structure dispensed onto an electrostatic field in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof.

The present invention relates generally to improving the conductivity of ink materials by passing radio frequency (RF) current through a structure. More particularly, the present disclosure relates to a conductive ink and method of creating a high performance RFID antenna using the printed conductive ink where the particle to particle connection is altered to improve conductivity. More specifically, a RF signal of a known level is applied to a printed conductive ink comprising a binder and a plurality of conductive particles oriented so as to have relatively poor conductivity, wherein the binder is in a pre-cured state. Application of the RF signal coheres the plurality of conductive particles to improve the conductivity of the ink. The binder is then cured, trapping the plurality of conductive particles in the cohered, lower resistant state.

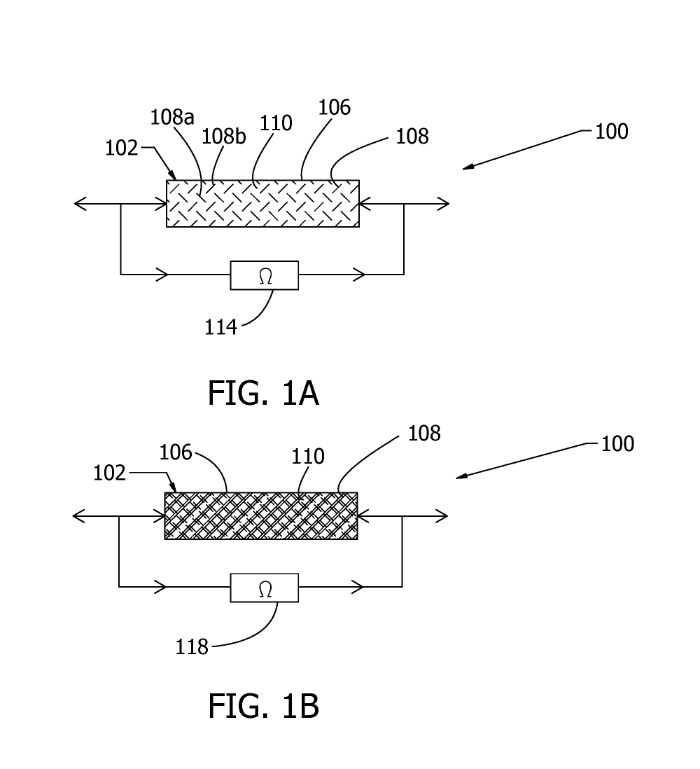

Referring initially to the drawings, FIGS. 1-9 illustrate a conductive structure and method of improving conductivity in the conductive structure. As illustrated in FIGS. 1-3, a conductive structure 100 comprised of a conductive ink 106 is disclosed. The conductive ink 106 is printable onto a surface 122. The conductive structure 100 is typically arranged in a printed shape 102, a path, a strip, an antenna shape, a RFID shaped antenna shape, and the like. The conductive ink 106 comprises a plurality of conductive particles 108 and a binder 110. The plurality of conductive particles 108 are either suspended in the binder 110 or are directly attachable to the surface 122.

As illustrated in FIG. 1A, the plurality of conductive particles 108 are initially aligned in a first orientation or pre-cohered state having a first resistance 114. The first resistance 114 is relatively high as the plurality of conductive particles 108 are not sufficiently oriented so as to have an efficient level of conductivity. In one example, the first resistance 114 may be 5,000 ohms or greater. FIG. 1B, illustrates the plurality of conductive particles 108 following exposure to a RF source 140. The RF source 140 coheres or repositions at least one or more of the plurality of conductive particles 108a relative to a second one or more of the plurality of conductive particles 108b. Following coherence, the plurality of conductive particles 108 are then aligned in a second orientation or cohered state having a second resistance 118. In one example the second resistance 118 may be 50 ohms or less. However, the goal is that the difference between the first resistance 114 and the second resistance 118 must achieve the desired conductivity for the given application.

Once coherence has achieved the second desired resistance 118, the binder 110 is activated or cured to maintain the conductive particles 108 in the second orientation with the increased conductivity. The binder 110 is typically cured using an external curing influence such as radiation, ultra-violet radiation, heat, pressure, sintering, a chemical process, or by any other method of curing a binder as known to one of skill in the art.

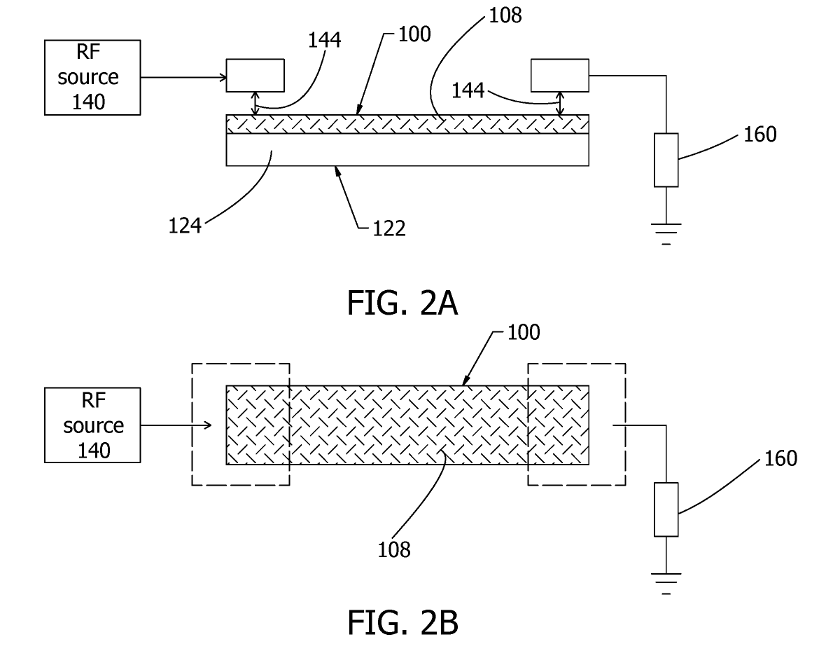

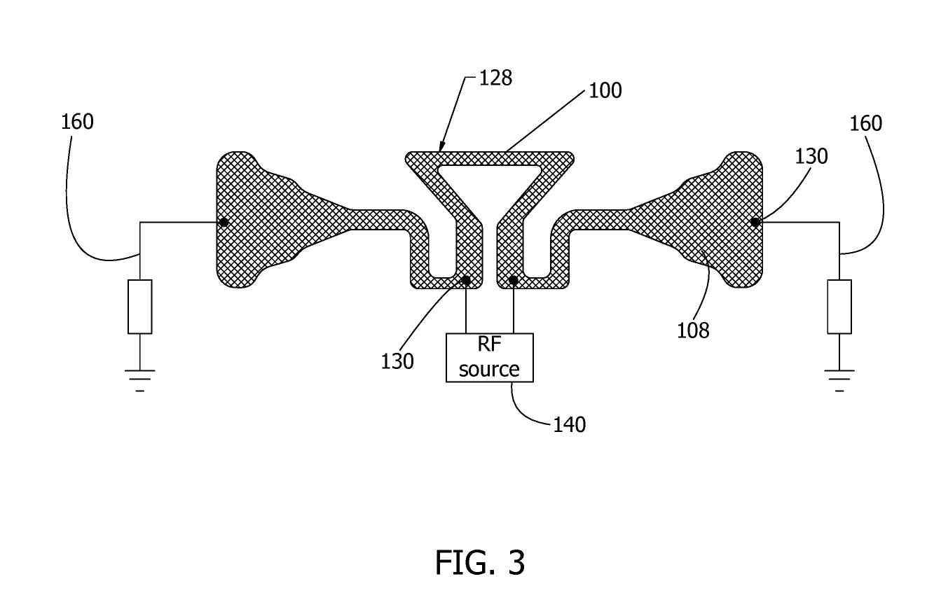

As illustrated in FIGS. 2A and 2B, the conductive structure 100 is printable onto surface 122, such as a base substrate 124. The RF source 140 may be coupled to the conductive structure 100 using capacitive coupling to achieve mutual capacitance. The RF source 140 may be oriented so as to partially overlap at least a portion of the conductive structure 100. As illustrated in FIGS. 2B and 3, a plurality of electrical terminations 160, such as resistors, may be connected to the conductive structure 100 so that coherence of the plurality of conductive particles 108 is enhanced through terminating impedance. The plurality of electrical terminations 160 are configured to ensure that a source signal or current from the RF source 140 flows to every part of the conductive structure 100 and/or the surface 122 that needs to be cohered to achieve the desired level of conductivity. Each of the plurality of electrical terminations 160 is locatable at an end of the conductive structure 100, or at any other position along conductive structure 100 so as to maximize coherence.

As illustrated in FIG. 3, the surface 122 to which the conductive structure 100 is applied may comprise an antenna 128. The antenna 128 may be a RF antenna, shaped in any form or geometry as desired. As such, the printable ink 106 may be directly printed onto or otherwise directly applied to the antenna 128. The RF source 140 would then be in direct contact or be directly coupled to the antenna 128 and the conductive structure 100. The antenna 128 may comprise a plurality of contacts 130. The plurality of contacts 130 may comprise a plurality of contact points 132 located on the antenna 122 so as to allow the RF source 140 to drive different positions along the antenna 122 to maximize coherence. Additionally, the RF source 140 may comprise more than one RF source.

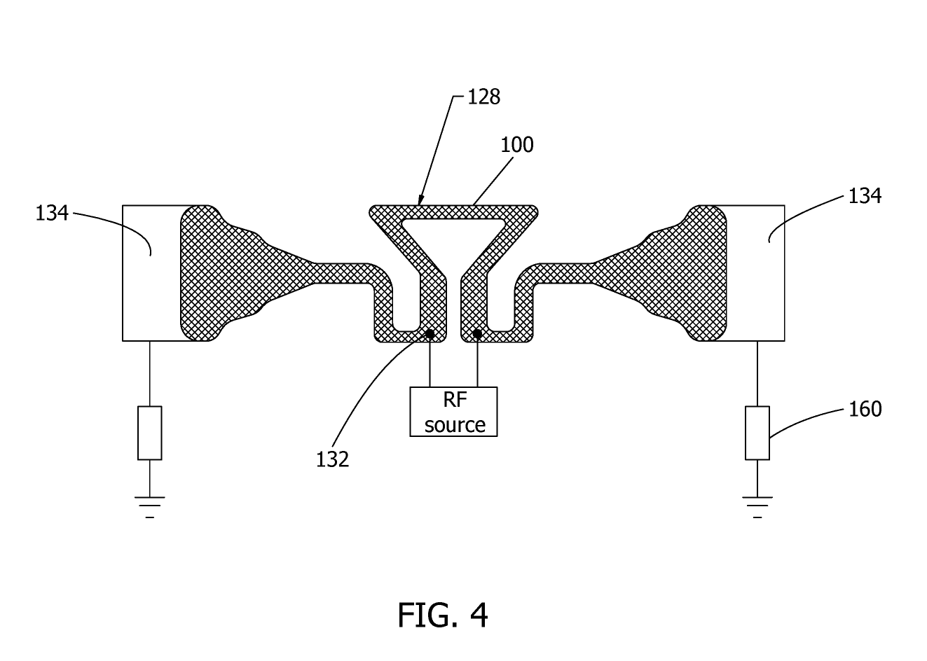

The application of the RF signal to one or more positions on the antenna 128, in combination with the terminating impedances, ensures that current flows to all parts of the conductive structure 100 that need to be cohered. The RF source 140 may be located at or near a central region of the antenna 128 and the conductive structure 100, or at any location determined to maximize effectiveness. Alternatively, FIG. 4 illustrates an embodiment where the plurality of contacts 132 further comprise a plurality of contact strips 134 locatable at different positions along the antenna 128 to maximize coherence. A combination of the plurality of contact points 132 and the plurality of contact strips 134 may be used with or without terminating impedance to maximize conductivity. Similarly, the RF source 140 may be located at a central region of the antenna 128 and the conductive structure 100, or at any location determined to maximize effectiveness.

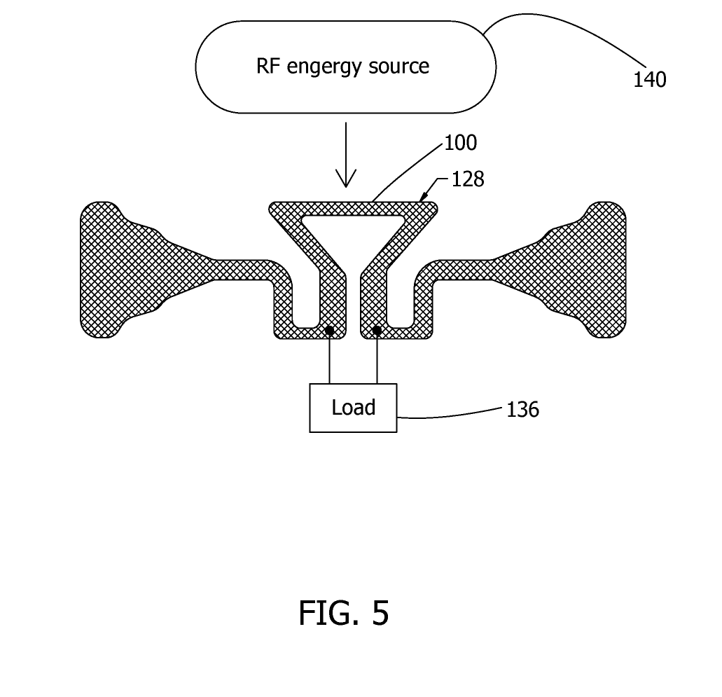

The RF source 140 may also be magnetically coupled (not shown) to the antenna 128 and the conductive structure 100; or as illustrated in FIG. 5, the RF source 140 may be a non-contact RF source. An impedance 136, such as a load, is attached to the antenna 128 via the plurality of contacts 130 where a RFID chip would typically be connected. The antenna 128 and conductive structure 100 may then be illuminated with an RF signal from the RF source 140 at or near a desired operational frequency for the final RFID tag. The RF current would then flow through the antenna 128 and the conductive structure 100 causing the associated paths to cohere. The RF source 140 may comprise a near field RF source or a far field RF source. As the plurality of conductive particles 108 cohere, the current will tend to follow the paths that would be the maximum current paths in operation as an RFID tag. Therefore, the resulting antenna 128 and the conductive structure 100 are conductively optimized for the required application. As coherence progresses, the RF characteristics, such as power delivered to the impedance 136 or reflected signal from the antenna 128 changes. When the parameters reach the desired state, the RF source 140 may be switched off.

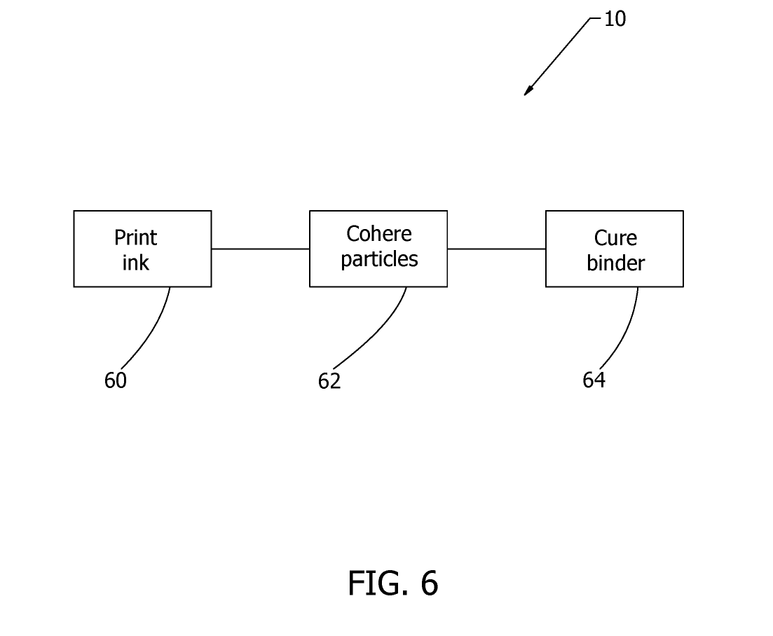

FIG. 6 illustrates a method 10 of increasing conductivity in ink. The method begins by selecting an ink 106 comprising a plurality of conductive particles 108 and a binder 110. At step 60, the ink 106 is printed onto a surface 122. The surface 122 may comprise a base substrate 124 or an antenna 128. A RF signal is applied from a RF source 144 at step 62 to lower the electrical resistance in the ink 106 by cohering the plurality of conductive particles 108. Once the plurality of conductive particles 108 are cohered at a desired level of conductivity, the binder 110 is cured at step 64 to maintain the lower resistance. Curing may be accomplished using an external influence such as, but not limited to, ultra-violet radiation, heat, a secondary chemical process, or the like.

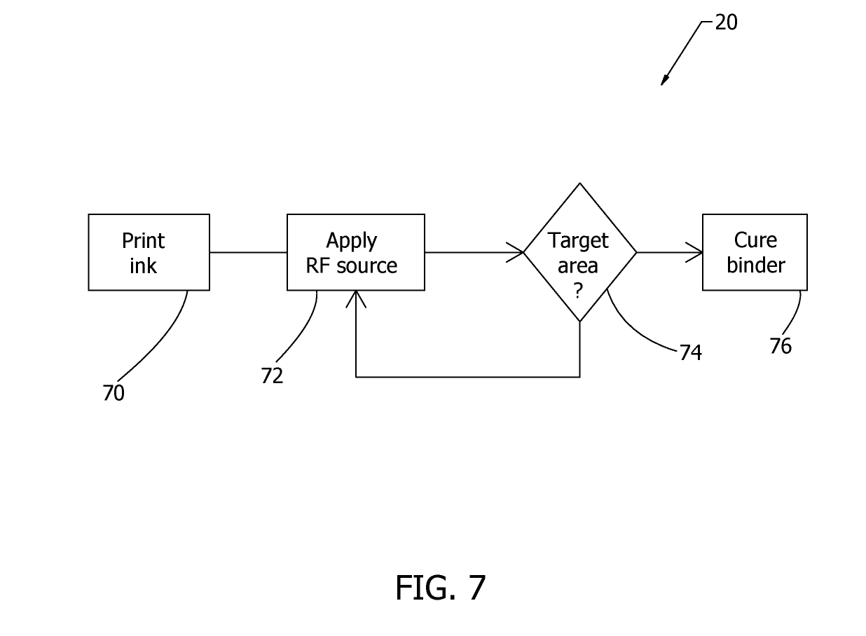

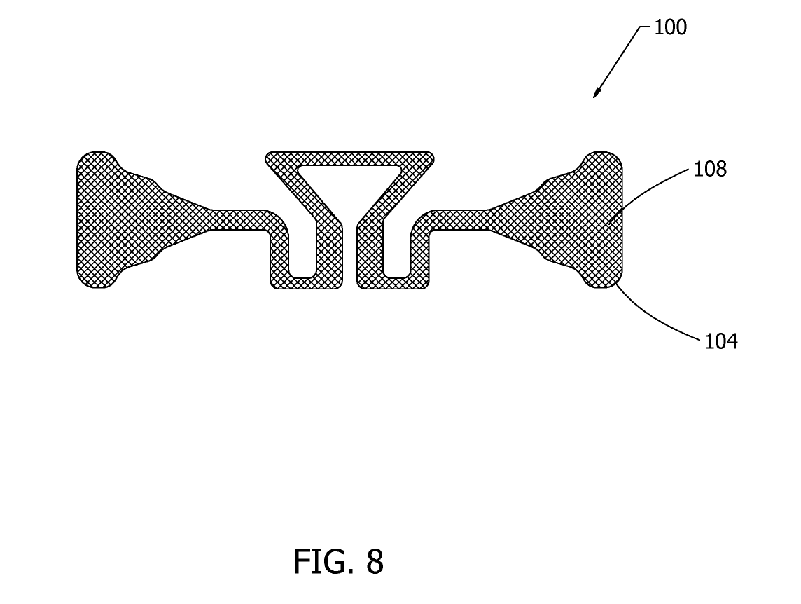

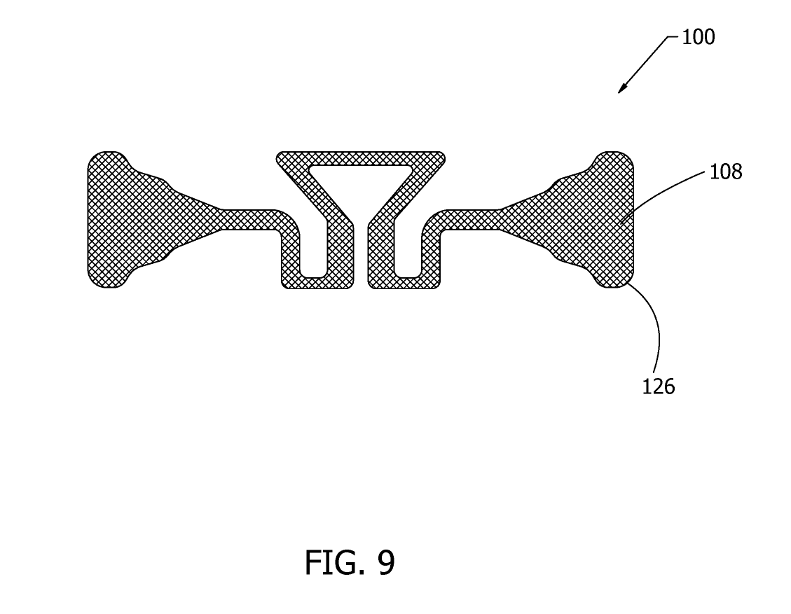

FIG. 7 illustrates a method of preparing a conductive structure 100 on a surface 122. The method begins at step 20 by selecting an ink 106 comprising a plurality of conductive particles 108 and a binder 110. At step 70, the ink 106 is printed onto a surface 122. The surface 122 may comprise a printed shape 102, a path, a strip, an antenna shape, an antenna 128, a pressure sensitive adhesive 104 as illustrated in FIG. 8, or a patterned electrostatic field 126 as illustrated in FIG. 9. At step 72, a RF source 140 is applied to the ink 106 to create coherence in the plurality of conductive particles 108. A feedback loop is illustrated, wherein a target for coherence of the plurality of conductive particles 108 is determined at step 74. A determination is made as to whether the ink 106 has a reduced electrical resistance, and whether the resistance is at an acceptable or desired level. A decision may then be made to either return to step 72 and reapply, or alter and reapply, the RF source 140 at a different power and/or frequency; or to switch the RF source 140 off if the resistance is at an acceptable level. The target may be measured in a variety of ways such as, but not limited to, determining RF measurements on the antenna 128 or point to point resistance checks. Once the resistance is determined to be at an acceptable level, the ink 106 is cured at step 76 to maintain the lower resistance as discussed supra.

As illustrated in FIG. 8, the plurality of conductive particles 108 may be dispensed onto or printed onto an adhesive 104. The adhesive 104 may also be a pressure sensitive adhesive, a hot melt, or the like. The adhesive 104 may be generally antenna shaped for application onto an antenna 128. A RF source 140 may then be applied to the adhesive 104 with the plurality of conductive particles 108 to generate coherence as described supra. The cohered adhesive 104 with the plurality of conductive particles 108 may also be protected with a protective layer or coating applied over the cured conductive structure. The protective layer may comprise a varnish, a chemical coating, a film, a layer or thin plastic, a layer of PET, or the like.

As illustrated in FIG. 9, the plurality of conductive particles 108 may be dispensed onto a patterned electrostatic field, and then processed by the methods discussed supra.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A method of increasing conductivity in ink comprising:
providing an ink having a plurality of conductive particles and a binder;
printing the ink onto a surface;
applying a radio frequency source to the ink to lower electrical resistance; and
curing the binder to maintain the lower electrical resistance.

2. The method of claim 1, wherein the plurality of conductive particles are suspended in the binder.

3. The method of claim 1, wherein the surface is an antenna.

4. The method of claim 3, wherein the antenna comprises a plurality of contacts.

5. The method of claim 4, wherein the plurality of contacts are contact strips.

6. The method of claim 1, wherein the surface is an adhesive.

7. The method of claim 1, wherein the radio frequency source is a non-contact source.

8. The method of claim 1, wherein the radio frequency source is a near field source.

9. The method of claim 1, wherein the radio frequency source a far field source.

10. The method of claim 1, wherein the binder is cured using radiation, sintering, heat, or a chemical process.

11. A method of preparing a conductive structure on a surface comprising:
printing an ink having a plurality of conductive particles and a binder on the surface;
applying a radio frequency source to the ink to create coherence in the plurality of conductive particles;
determining an electrical resistance of the ink; and
curing the binder.

12. The method of claim 11, wherein the plurality of conductive particles are attached to the surface.

13. The method of claim 11, wherein the surface is an antenna.

14. The method of claim 11, wherein the radio frequency source is capacitively coupled to the conductive structure.

15. The method of claim 11, wherein the plurality of conductive particles are dispensed onto a patterned electrostatic field.

16. The method of claim 11, further comprising the step of applying a protective layer over the conductive structure once the binder is cured.

17. The method of claim 11, wherein coherence in the plurality of conductive particles is increased via terminating impedance.

18. The method of claim 11, wherein the radio frequency source is in direct contact with the conductive structure.

19. A conductive ink printable on a surface comprising:
a plurality of conductive particles; and
a binder; and
wherein one or more of the plurality of conductive particles are repositioned relative to a second one or more of the plurality of conductive particles in response to a radio frequency signal, and further wherein the binder maintains the repositioning.

20. The conductive structure of claim 19, wherein the surface is an antenna.
